(19) United States
(12) Patent Application Publication
(10) Pub. No.: US 2008/0064218 A1
(43) Pub. Date: Mar. 13, 2008

(54) MANUFACTURING METHOD FOR PREVENTING IMAGE SENSOR FROM UNDERCUT

(76) Inventor: Joo-Hyun Lee, Seoul (KR)

Correspondence Address: SHERR & NOURSE, PLLC, 620 HERNDON PARKWAY, SUITE 200, HERNDON, VA, 20170, US

(21) Appl. No.: 11/844,564

(22) Filed: Aug. 24, 2007

(30) Foreign Application Priority Data
Sep. 12, 2006 (KR) 10-2006-0087755

(51) Int. Cl. H01L 21/311; H01L 21/306

(52) U.S. Cl. 438/703; 156/345.1; 257/E21.249

(57) ABSTRACT

Embodiments relate to an image sensor, and in particular to a manufacturing method of an image sensor for preventing an undercut phenomenon in an etching process so that the salicidation of a pixel area can be prevented. Embodiments relate to a manufacturing method of an image sensor for preventing an undercut according to embodiments including forming plasma-enhanced tetra ethyl ortho silicate (PE-TEOS) films in a non-salicide area and a salicide area defined over a semiconductor substrate using a CVD process. A photoresist pattern may be formed covering the salicide area over the PE-TEOS films. A nitridation process may be performed over the PE-TEOS films formed over the non-salicide area using plasma. The photoresist pattern is removed. The non-nitrided PE-TEOS films of the PE-TEOS films may be removed using an etching process.

The present application claims priority under 35 U.S.C. 119 to Korean Patent Application No. 10-2006-0087755, filed on Sep. 12, 2006, which is hereby incorporated by reference in its entirety.

### BACKGROUND

An image sensor is a device that converts an optical image into an electrical signal. The image sensor can largely be classified into a complementary metal-oxide-silicon (CMOS) image sensor and a charge coupled device (CCD) image sensor. The CCD image sensor has excellent characteristics in photo sensitivity and noise as compared to the CMOS image sensor. The CCD, however, is difficult to integrate at high densities and consumes large amounts of power. In contrast, the CMOS image sensor is relatively simple to manufacture, suitable for high integration, and low in power consumption, as compared to the CCD image sensor. As manufacturing technology of semiconductor devices develops, characteristics of the CMOS image sensor may be maximized. Advances in CMOS image sensor technology have been actively progressing.

A pixel of a CMOS image sensor includes photo diodes receiving light and associated devices controlling image signals input from the photo diodes. In the photo diodes, electron/hole pairs are generated according to the wavelength and intensity of red light, green light, and blue light incident through color filters. An output signal varies according to the number of generated electrons so that an image can be sensed electronically. A CMOS image sensor includes a pixel area in which the photo diodes are formed and a peripheral circuit area for detecting the signals detected in the pixel area. The peripheral circuit area is positioned to surround the pixel area. A CMOS image sensor may use wet etching and dry etching processes for defining a non-salicide area and a salicide area. In particular, it is important that the pixel area is defined in the non-salicide area.

FIG. 1 is an example of an undercut phenomenon generated in a manufacturing method of an image sensor in the related art. When defining the non-salicide area and the salicide area using dry etching, the characteristics of the CMOS image sensor are degraded by plasma used in the etching. The non-salicide area and the salicide area may also be defined using wet etching. When the wet etching progresses toward the lower of the photoresist by means of the isotropic characteristics of the wet etching, the undercut phenomenon occurs as shown in FIG. 1. An undercut of about 100 nm or more may occur. Such an undercut generates salicide in the pixel area to fatally damage the pixel area, which should be a non-silicide area, thereby degrading the characteristics of the CMOS image sensor.

### SUMMARY

Embodiments relate to a manufacturing method of an image sensor, and in particular to a manufacturing method for preventing an image sensor from an undercut caused in the course of performing a salicide process. Embodiments relate to a manufacturing method of an image sensor capable of preventing an undercut phenomenon caused by wet etching to define a non-salicide area and a salicide area.

Embodiments relate to a manufacturing method of an image sensor for preventing an undercut according to embodiments including forming plasma-enhanced tetra ethyl ortho silicate (PE-TEOS) films in a non-salicide area and a salicide area defined over a semiconductor substrate using a CVD process. A photoresist pattern may be formed covering the salicide area over the PE-TEOS films. A nitridation process may be performed over the PE-TEOS films formed over the non-salicide area using plasma. The photoresist pattern is removed. The non-nitrided PE-TEOS films of the PE-TEOS films may be removed using an etching process.

### DRAWINGS

FIG. 1 shows an example of an undercut phenomenon caused by a manufacturing method of an image sensor in the related art.

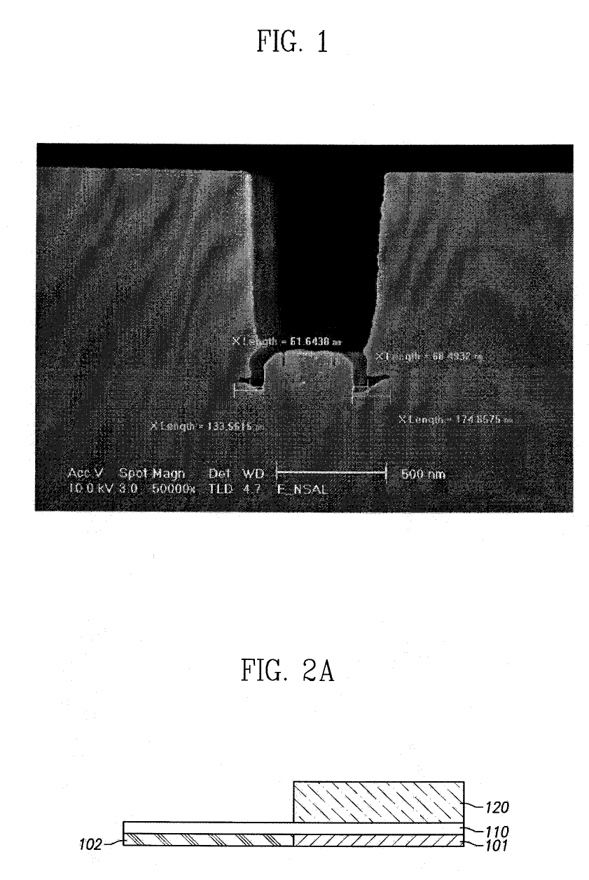

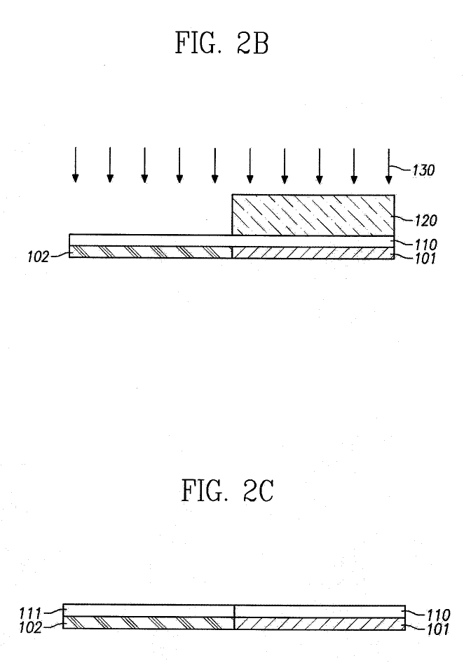

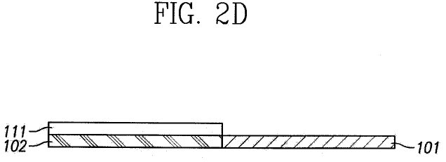

Example FIGS. 2a to 2d are cross-sectional views of a manufacturing method of an image sensor according to the embodiments.

### DESCRIPTION

Example FIGS. 2a to 2d are cross-sectional views of a manufacturing method of an image sensor according to the embodiments. As shown in example FIG. 2a, a plasma-enhanced tetra ethyl ortho silicate (PE-TEOS) film 110 may be formed for a non-salicide area 102 and a salicide area 101 defined over the semiconductor substrate at a thickness of about 5 to 40 nm using a chemical vapor deposition (CVD) process. A patterning process, which forms a photoresist pattern covering the salicide area 101 at a predetermined thickness, may be performed on the formed PE-TEOS film 110.

Subsequently, as shown in example FIG. 2b, a nitridation process may be performed over the PE-TEOS film 110 formed over the non-salicide area 102 using plasma. The conditions of the nitridation process using the plasma are that atmospheric pressure is approximately 10 mtorr or more, and RF power between approximately 200W and 1500W is applied. Under these conditions, the nitridation process using the plasma may be performed for approximately 10 seconds by inletting N₂ gas so that nitrogen ions may be implanted into the PE-TEOS film (110) formed over the non-salicide areas 102.

After the nitrogen ions are implanted into the PE-TEOS film 110, if the photoresist pattern 120 is stripped using, for example, H₂SO₄ and H₂O₂ in order to remove the photoresist pattern 120, the nitrided PE-TEOS film 111 and the PE-TEOS film 110 are formed as shown in example FIG. 2c.

An etching process may be performed in order to remove only the PE-TEOS film 110. Herein, the etching process for removing only the PE-TEOS film 110 uses a mixture of H₂O₂ and HF:BHF having a mixing ratio between approximately 100:1 to 1000:1. The selectivity of the HF or the BHF in the nitrided PE-TEOS film 111 and the PE-TEOS film 110 becomes about 4:1 to about 20:1 according to the extent of the nitridation.

The non-salicide area 102 and the salicide area 110 can be classified and defined without causing the undercut phenomenon in the etching process because of the selectivity of the HF or the BHF for a nitrided PE-TEOS film 111 and the PE-TEOS film 110.

Therefore, wet etching of the PE-TEOS film 110 may be implemented without the undercut phenomenon so that the salicidation of the pixel area may be prevented. The non-salicide area 102 and the salicide area 101 are processed so that the image characteristics of the image sensor can be improved. Embodiments above may classify and define the non-salicide area and the salicide area without causing the undercut phenomenon in the etching process so that the salicidation of the pixel area can be prevented, making it possible to improve the image characteristics of the image sensor.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming plasma-enhanced tetra ethyl ortho silicate films in a non-salicide area and a salicide area defined over a semiconductor substrate using a chemical vapor deposition process;
forming a photoresist pattern covering the salicide area over the plasma-enhanced tetra ethyl ortho silicate films;
performing a nitridation process over the plasma-enhanced tetra ethyl ortho silicate films formed over the non-salicide area using plasma;
removing the photoresist pattern; and
removing non-nitrided plasma-enhanced tetra ethyl ortho silicate films using an etching process.

2. The method of claim 1, wherein the plasma-enhanced tetra ethyl ortho silicate films are formed at a thickness between approximately 5 and 40 nm.

3. The method of claim 1, wherein the nitridation process uses nitrogen plasma for about 10 seconds.

4. The method of claim 3, wherein the nitridation process inlets N₂ gas at a pressure of about 10 mtorr or more.

5. The method of claim 4, wherein the nitridation process uses radio frequency power between approximately 200 watts and 1500 watts.

6. The method of claim 1, wherein the photoresist pattern is removed using H₂SO₄ and H₂O₂.

7. The method of claim 1, wherein the removing of the non-nitrided plasma-enhanced tetra ethyl ortho silicate film using the etching process is performed using etchant that is a mixture of H₂O₂ and HF:BHF.

8. The method of claim 7, wherein said mixture of H₂O₂ and HF:BHF has a mixing ratio of 100:1 to 1000:1.

9. The method of claim 8, wherein the selectivity of the HF or the BHF of the nitrided plasma-enhanced tetra ethyl ortho silicate film and the non-nitrided plasma-enhanced tetra ethyl ortho silicate film is between about 4:1 to 20:1 according to the extent of the nitridation.

10. The method of claim 1, comprising forming an image sensor.

11. The method of claim 10, comprising preventing an undercut phenomenon.

12. An apparatus configured to:
form plasma-enhanced tetra ethyl ortho silicate films in a non-salicide area and a salicide area defined over a semiconductor substrate using a chemical vapor deposition process;
form a photoresist pattern covering the salicide area over the plasma-enhanced tetra ethyl ortho silicate films;
perform a nitridation process over the plasma-enhanced tetra ethyl ortho silicate films formed over the non-salicide area using plasma;
remove the photoresist pattern; and
remove non-nitrided plasma-enhanced tetra ethyl ortho silicate films using an etching process.

13. The apparatus of claim 11, wherein the plasma-enhanced tetra ethyl ortho silicate films are formed at a thickness between approximately 5 and 40 nm.

14. The apparatus of claim 11, wherein the nitridation process uses nitrogen plasma for about 10 seconds.

15. The apparatus of claim 14, wherein the nitridation process inlets N₂ gas at a pressure of about 10 mtorr or more.

16. The apparatus of claim 15, wherein the nitridation process uses radio frequency power between approximately 200 watts and 1500 watts.

17. The apparatus of claim 12, wherein the photoresist pattern is removed using H₂SO₄ and H₂O₂.

18. The apparatus of claim 12, wherein the non-nitrided plasma-enhanced tetra ethyl ortho silicate film are removed using the etching process is performed using etchant that is a mixture of H₂O₂ and HF:BHF.

19. The apparatus of claim 18, wherein said mixture of H₂O₂ and HF:BHF has a mixing ratio of 100:1 to 1000:1.

20. The apparatus of claim 19, wherein the selectivity of the HF or the BHF of the nitrided plasma-enhanced tetra ethyl ortho silicate film and the non-nitrided plasma-enhanced tetra ethyl ortho silicate film is between about 4:1 to 20:1 according to the extent of the nitridation.
